(19) United States
(12) Patent Application Publication
(10) Pub. No.: US 2023/0267240 A1
(43) Pub. Date: Aug. 24, 2023

(54) A SYSTEM FOR MANAGING THE PROGRESS OF CONSTRUCTION BASED ON LIDAR TECHNOLOGY

(71) Applicant: Wai Man Raymond LAU, Hong Kong (HK)

(72) Inventor: Wai Man Raymond LAU, Hong Kong (HK)

(21) Appl. No.: 18/015,255

(22) PCT Filed: Oct. 11, 2021
(86) PCT No.: PCT/IB2021/059273

§ 371 Date: Jan. 9, 2023

(30) Foreign Application Priority Data
Oct. 19, 2020 (HK) 32020018290.7

(51) Int. Cl. G06F 30/13; G01S 17/89

(52) U.S. Cl. CPC G06F 30/13; G01S 17/89; G06Q 50/08

(57) ABSTRACT

The invention provides a system for construction progress management based on LiDAR technology, comprising a cloud server containing a BIM of a building under construction or in operation; and a handheld measurement device with a LiDAR and a positioning device. The user uses the handheld LiDAR scan at a specified location in the building and obtains point cloud data of the building structure in real time, which is transmitted via the network to the cloud server, where the cloud server obtains the comparison results and the attribute data of the building components in real time by comparing the real time measurement data with the historical measurement data and/or the building BIM, and then uses augmented/mixed reality to display on the handheld measurement device’s display screens so that users with different access rights can quickly, directly and clearly understand the progress and quality of the work, etc.

### FIELD OF THE INVENTION

The invention relates to a system for measuring buildings using LiDAR technology and comparing it with BIM to enable the management of building progress and builders, property managers, and operators.

### BACKGROUND OF THE INVENTION

BIM (Building Information Modeling) can help to realize the integration of building information, from the design, construction and operation of a building to the end of the building’s entire lifecycle. All kinds of information are eventually integrated into a three-dimensional model information database, the design team, construction units, facility operation and management department, owners and other parties can be involved based on BIM to cooperate and coordinate, and to improve work efficiency, save resources, reduce costs, and achieve sustainable development goals.

The core of BIM is to establish a virtual three-dimensional model of the building project and, through the use of digital technologies, to provide/enhance this model with a holistic and realistic database of information about the building project. The information database contains not only geometric information, professional parameters and attributes, project properties and overall conditions, and information describing the building components, but also contains the information of non-physical components/objects (e.g. spatial, motional, and behavioral data). With the help of this robust three-dimensional model which contains engineering and other information, the accuracy and comprehensive of information integration in building engineering is greatly improved, thereby providing a platform for the exchange, sharing, and coordination of information between the stakeholders of the building project.

In addition to the use of software such as BIM to manage the building model, in order to ensure that large construction projects are implemented in accordance with the established designs and construction schedule, it is necessary to monitor the progress of the construction project, of which the quality is the most important and critical part. The current monitoring progress of construction works is to assign supervisors to regularly visit the construction site to measure and check the progress of completed works to ensure the compliance of the construction requirements. However, the traditional monitoring process cannot make use or effective applications of the BIM model to follow up on the quality and progress of the project in real time.

### SUMMARY OF THE INVENTION

In view of the aforesaid drawbacks of the prior art, the present invention provides a system for managing the progress of construction based on LiDAR technology. Users can obtain the measurement data by scanning the construction site in real time by using a handheld LiDAR device, and then compare the real time measurement data with the historical measurement data to facilitate real time checking of construction progress.

The invention achieves this by. :

A system for managing the progress of construction based on LiDAR technology, comprises a cloud server and a handheld measurement device; the handheld measurement device is provided with a LiDAR and a positioning device; the system is used to monitor the construction progress of the building which includes the following steps:
S1. enter the building with the handheld measurement device, measure the building using the LiDAR of the handheld measurement device and record the measurement data, and the positioning device records the positioning data of the measurement location;
S2. The handheld measurement device transmits the measurement data and positioning data in real time to the cloud server, which records the measurement data, positioning data and measurement time; and according to the positioning data it retrieves, the historical measurement data recorded at the same position is retrieved and compared with the real time measurement data to generate the comparison result data.
S3. The server transfers the comparison result data in real time to the handheld measurement devices to show the comparison result data through the display devices for augmented/mixed reality display.

Further, the handheld measurement device is further provided with a camera device which records the image data simultaneously with the measurement of the building by LiDAR and transmits the image data to the cloud server.

Further, in step S3, the handheld measurement devices convert the comparison result data into graphic data and superimposes it on the image data from the camera device, and then sent to the display devices for augmented/mixed reality display; specific step is: the cloud server sets a specified error range, compares the measurement data with the historical measurement data recorded and calculates a deviation value; if the deviation value is within the specified error range, the measurement data is considered to be consistent with the historical measurement data; otherwise, the measurement data is inconsistent with the historical measurement data recorded, and the deviation value is formed as a quality inspection data, and the quality inspection data is highlighted in the display devices.

Further, the cloud server provides a BIM of the building under construction, the real-time measurement data is compared with the BIM data for construction quality management, which comprises the following steps: the handheld measurement device transmits the measurement data and positioning data to the cloud server in real time, the cloud server retrieves the BIM data in the BIM of the building according to the positioning data, compares the measurement data with the BIM data and generates the quality inspection data; the cloud server transmits the quality inspection data to the handheld measurement devices in real time, the display device of the handheld measurement device displays augmented/mixed reality display.

Further, the cloud server sets the specified error range, compares the measurement data with the BIM data and calculates the deviation value, if the deviation value is within the error range, the measurement data is consistent with the BIM data; otherwise, the measurement data is inconsistent with the BIM data, the deviation value is formed into quality inspection data, and the quality inspection data is highlighted in the display devices.

Further, attribute data of the building is stored in said building BIM, the cloud server transmits the attribute data of the building components in real time to handheld measurement devices, and the display device of the handheld measurement devices display the attribute data in real time.

Further, while the measurement data is inconsistent with the BIM data, the graphic data formed by the handheld measurement devices highlights the measurement data in real time on the display devices and issues an alert.

Further, the positioning device comprises visible light wireless communication devices distributed in the building and provided in the handheld measurement devices for communication, the visible light wireless communication devices in the handheld measurement devices are connected to one of the visible light wireless communication devices in the building, and the handheld measurement devices are positioned according to the position of the visible light wireless communication devices in the building; the handheld measurement devices are positioned according to the location of the building’s visible light wireless communication devices, and the handheld measurement devices are connected to the cloud server through the visible light wireless communication devices.

Further, the positioning devices are iBeacon positioning devices or QR Codes, Barcodes, RFIDs and indoor mobile network positioning devices in the building site, such as 4G, 5G positioning devices.

Further, the cloud server uses blockchain-based data storage, which is including a measurement records and timings/time-stamps database, a building component properties database, a BIM database of the building, and a user rights and information database.

The beneficial effects of the present invention are: the users scan the building structures, components and equipment at the designated locations of the building with a handheld LiDAR devices, and obtains 3D measurement data of the building structures, components and equipment in real time, i.e. point cloud data, which is transmitted to the cloud server through the network. While the building is scanned by LiDAR, the current measurement data is created in the cloud server and can be compared as time shifts to obtain a clear picture of the building’s construction progress and quality. The results are then displayed on the handheld measurement devices by Augmented Reality/Mixed Reality, for example in different colours or shapes. This allows the user to quickly, directly and clearly understand what works have been completed, what are in progress and what the properties of the building components are, making it easier to understand the progress of construction and to record and report on the progress of the project, as well as the relevant personnel who can be automatically or manually notified through the cloud system to follow up the works.

### BRIEF DESCRIPTION OF THE DRAWINGS

The invention is further illustrated in the accompanying drawings as follows.

FIG. 1 shows a schematic view of the front of the handheld measurement device.

FIG. 2 shows a schematic view of the back of the handheld measurement device.

FIG. 3 is a schematic diagram of the system architecture.

In the picture, 1. LiDAR, 2. camera device.

### DESCRIPTION OF THE EMBODIMENTS

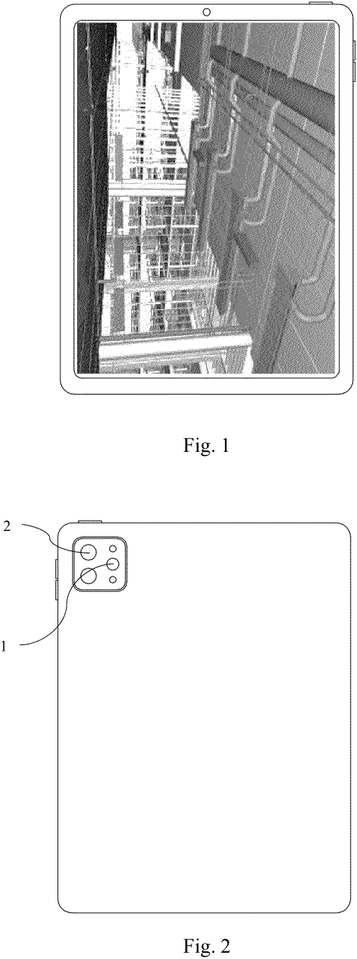

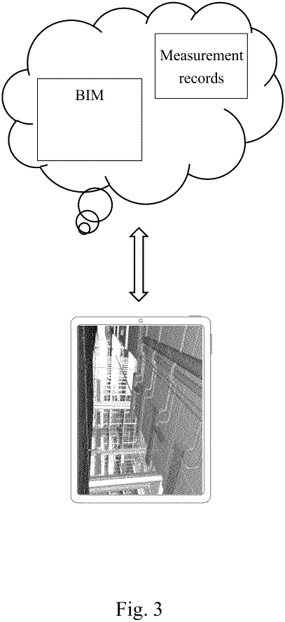

With reference to FIG. 1 and FIG. 2, the system for managing the progress of construction based on LiDAR (Light Detection and Ranging) technology, comprises a cloud server in which a BIM of the building under construction is loaded; and a handheld measurement device in which LiDAR 1 and a positioning device. The handheld measurement device can be a laptop, mobile phone or tablet computer etc., such as Apple’s iPad Pro 2020, which has a LiDAR 1 module at the location of its camera. When the building cannot receive GPS signals, its positioning device needs to adopt corresponding technologies that can achieve indoor positioning functions, such as QRCode, RFID, Wifi, UWB, Bluetooth, infrared, ultrasound, ZigBee, indoor mobile networks such as 4G, 5G and other indoor positioning technologies that are commonly available on the market, of which Apple’s iBeacon positioning technology uses the Bluetooth module inside the mobile phone or tablet to communicate with the external iBeacon communication modules for positioning.

In addition to the above-mentioned positioning devices, indoor positioning can also be achieved by using Visual Light Communication (VLC) technology, which requires VLC devices to be distributed and set up in the building as required. Due to the high frequency, the human eye cannot detect the flickering of the LEDs and it does not affect the normal lighting, and communication can only be effective in the area covered by the visible light emitted by the LEDs. The handheld measurement device can also be connected to a cloud server for data transmission via the VLC device.

Through the indoor positioning device, the location of the building is recorded in real time when the user uses LiDAR 1 to measure the building, and the positioning data and the point cloud data measured by LiDAR 1 are transferred to the cloud server so that the cloud server can compare the model data of BIM with the point cloud data at the corresponding location in the BIM based on the positioning data. At the same time, the cloud server also records the time of measurement, enabling the management of project progress through time recording / time-stamps.

The method of managing the construction progress of a building using the above-mentioned devices consists of the following steps:

S1. The user enters the designated inspection location of the building with the handheld measurement device according to the pre-determined monitoring schedule and uses the LiDAR 1 of the handheld measurement device to measure the structures at that location to form point cloud data, while the positioning device records the positioning data of the measurement location.

S2. The handheld measurement equipment transmits point cloud data and positioning data to the cloud server in real time through wireless networks such as mobile data networks, Wifi, Bluetooth, etc. and records the measurement time, and the cloud server can manage the construction progress and construction quality after obtaining the point cloud data and positioning data.

For construction progress management: the cloud server will first retrieve the historical measurement data recorded at the location from the database based on the location data, usually the last completed measurement data, and compare the real time measurement data with the historical measurement data to find the difference between the real time measurement data and the historical measurement data, and the difference is the construction progress completed during this period of time; the cloud server will then record these differences and then generate the resultant data.

For construction quality management: the cloud server uses the point cloud data to construct a real time 3D building model of the site, and then compares the 3D building model with the BIM data. Specifically, the point cloud data is compared with the BIM data and the deviation value is calculated. If the deviation value is within the error range, the point cloud data of the building component is considered to be consistent with the BIM data and the specification of the building component meets the BIM design requirements. However, if the deviation value is out of the error range, the building component may not be completed or the specification of the building component is out of the BIM design requirements, and the cloud server will record the deviation value to form the comparison result data.

S3. The cloud server also transfers the comparison result data to the handheld measurement devices in real time. In addition to LiDAR 1, the handheld measurement device is equipped with a camera device 2, such as a camera lens, to record the image information of the building components measured by LiDAR 1 in real time and to display the image information in real time on its display. At the same time, the comparison result data is converted into graphic data and superimposed on the live or recorded image of the camera for displays, enabling the displays of augmented/mixed reality technology and issuing alerts. For example, if the specifications of the building components comply with the design in BIM, different confirmation colours such as green, blue etc. can be rendered on the contour of the building components captured in real time; if the specifications of the building components do not comply with the requirements of the BIM design, the design data in the BIM will be displayed in alarming colours, such as red, orange, yellow and other outlines. So that the user can easily observe the construction progress and quality of each building component in real time.

In addition, the BIM of the building will also store the attribute data of the building components. As the building components on site may not be completed and have no identification tags, the user may not be able to identify the building components by direct observation, but by comparing the point cloud data with the BIM, the cloud server can intelligently identify the different building components in the point cloud data and then transmit the identified building components’ property data to the handheld measurement device in real time, such as the name, specification, requirements, etc. of the building components. The display of the handheld measurement devices can show the user the attribute data of various building components in real time so that the user can quickly identify and inspect them.

The above mentioned construction progress management and quality management are not only limited to the construction of buildings or building components, but may also involve the installation and layout of other objects in the BIM design of buildings, such as the laying of building piping, the placement, quantity and specification of firefighting equipment, lighting, signage, etc. As long as all the objects are provided in the BIM design, the system and method provided by the present invention can be used to effectively manage the construction progress and quality. Such function is not limited to use in buildings under construction, but can also be extended to buildings already in operation, giving property management staff more convenient and efficient management.

To ensure the reliability of the data in the cloud, the cloud server uses blockchain-based data storage, including a database of measurement records and a database of building BIM. Blockchain technology ensures that the data is not modified after it has been stored, thus ensuring the reliability and legal validity of the data.

It is also possible to set up users with different permissions for different personnel. Each user’s information of LiDAR 1 can be used as reference data for other related and/or project users.

1. A system for managing the progress of construction based on LiDAR technology, comprising a cloud server and a handheld measurement device; the handheld measurement device is provided with a LiDAR and a positioning device; the system is used to monitor the construction progress of the building which includes the following steps:
S1. enter the building with the handheld measurement device, measure the building using the LiDAR of the handheld measurement device and record the measurement data, and the positioning device records the positioning data of the measurement location;
S2. The handheld measurement device transmits the measurement data and positioning data in real time to the cloud server, which records the measurement data, positioning data and measurement time; and according to the positioning data, it retrieves, the historical measurement data recorded at the same position is retrieved and compared with the real time measurement data to generate the comparison result data.
S3. The server transfers the comparison result data in real time to the handheld measurement devices to show the comparison result data through the display devices for augmented/mixed reality display.

2. The system for managing the progress of construction based on LiDAR technology of claim 1, wherein the handheld measurement device is further provided with a camera device which records the image data simultaneously with the measurement of the building by LiDAR and transmits the image data to the cloud server.

3. The system for managing the progress of construction based on LiDAR technology of claim 2, wherein in step S3, the handheld measurement device converts the comparison result data into graphic data and superimposes it on the image data of the camera device, and then sent to the display devices for augmented/mixed reality display; specific step is: the cloud server sets a specified error range, compares the measurement data with the historical measurement data recorded and calculates a deviation value; if the deviation value is within the specified error range, the measurement data is considered to be consistent with the historical measurement data; otherwise, the measurement data is inconsistent with the historical measurement data recorded, and the deviation value is formed as a quality inspection data, and the quality inspection data is highlighted in the display devices.

4. The system for managing the progress of construction based on LiDAR technology of claim 1, wherein the cloud server provides a BIM of the building under construction, the real-time measurement data is compared with the BIM data for construction quality management, which comprises the following steps:
the handheld measurement device transmits the measurement data and positioning data to the cloud server in real time, the cloud server retrieves the BIM data in the BIM of the building according to the positioning data, compares the measurement data with the BIM data and generates the quality inspection data; the cloud server transmits the quality inspection data to the handheld measurement devices in real time, the display device of the handheld measurement device displays augmented/mixed reality display.

5. The system for managing the progress of construction based on LiDAR technology of claim 4, wherein the cloud server sets the specified error range, compares the measurement data with the BIM data and calculates the deviation value, if the deviation value is within the error range, the measurement data is consistent with the BIM data; otherwise, the measurement data is inconsistent with the BIM data, the deviation value is formed into quality inspection data, and the quality inspection data is highlighted in the display devices.

6. The system for managing the progress of construction based on LiDAR technology of claim 4, wherein attribute data of the building is stored in said building BIM, the cloud server transmits the attribute data of the building components in real time to handheld measurement devices, and the display device of the handheld measurement devices display the attribute data in real time.

7. The system for managing the progress of construction based on LiDAR technology of claim 4, wherein while the measurement data is inconsistent with the BIM data, the graphic data formed by the handheld measurement devices highlight the measurement data in real time on the display devices and issues an alert.

8. The system for managing the progress of construction based on LiDAR technology of claim 1, wherein the positioning device comprises a visible light wireless communication device distributed in the building and provided in the handheld measurement devices for communication, the visible light wireless communication device in the handheld measurement devices are connected to one of the visible light wireless communication devices in the building, and the handheld measurement devices are positioned according to the position of the visible light wireless communication devices in the building; the handheld measurement devices are positioned according to the location of the building’s visible light wireless communication devices, and the handheld measurement devices are connected to the cloud server through the visible light wireless communication devices.

9. The system for managing the progress of construction based on LiDAR technology of claim 1, wherein the positioning devices are iBeacon positioning devices or QR Codes, Barcodes, RFIDs, and indoor mobile network positioning devices in the building site.

10. The system for managing the progress of construction based on LiDAR technology of claim 1, wherein the cloud server uses blockchain-based data storage, which is including a measurement records and timings database, a building component properties database, a BIM database of the building, and a user rights and information database.
